(19) United States
(12) Patent Application Publication
(10) Pub. No.: US 2025/0179632 A1
(43) Pub. Date: Jun. 5, 2025

(54) SURFACE INHIBITION ATOMIC LAYER DEPOSITION

(71) Applicant: Lam Research Corporation, Fremont, CA (US)

(72) Inventors: Tao ZHANG, Tigard, OR (US); Pulkit AGARWAL, Beaverton, OR (US); Joseph R. ABEL, West Linn, OR (US); Shiva Sharan BHANDARI, Sherwood, OR (US); Jennifer Leigh PETRAGLIA, Lake Oswego, OR (US)

(21) Appl. No.: 18/842,017

(22) PCT Filed: Feb. 28, 2023
(86) PCT No.: PCT/US2023/063389

§ 371 Date: Aug. 27, 2024

Related U.S. Application Data
(60) Provisional application No. 63/314,995, filed on Feb. 28, 2022.

(51) Int. Cl. C23C 16/455; C23C 16/04; C23C 16/44; H01L 21/02

(52) U.S. Cl. CPC C23C 16/45534; C23C 16/045; C23C 16/4408; C23C 16/45536; H01L 21/02274; H01L 21/0228

(57) ABSTRACT

Atomic layer deposition (ALD) of dielectric material in gaps that facilitates void-free bottom-up gap fill can involve flowing a reaction inhibitor during the ALD process. In some embodiments, the reaction inhibitor is flowed during at least part of a plasma operation of a plasma-enhanced ALD (PEALD) process.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety.

### BACKGROUND

Many semiconductor device fabrication processes involve forming dielectric films such as silicon oxide. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Described herein are atomic layer deposition (ALD) processes to deposit dielectric material in gaps. A reaction inhibitor is flowed during the ALD process. In some embodiments, the reaction inhibitor is flowed during at least part of a plasma operation of a plasma-enhanced ALD (PEALD) process. The methods facilitate void-free bottom-up gap fill.

One aspect of the disclosure relates to a method for filling a gap of a substrate in a chamber, the method including: performing one or more cycles of:
(a) exposing the substrate to a first reactant;
(b) after (a), purging the chamber of the first reactant;
(c) after (b), exposing the substrate to a co-reactant plasma to drive a reaction between the first reactant and the co-reactant to form a film in the gap; and
(d) exposing the substrate to a reaction inhibitor during at least part of (c).

In some embodiments, the film is a silicon-containing film. In some embodiments film is an oxide, a nitride, or a carbide.

In some embodiments, (c) includes flowing a co-reactant to the chamber at a first volumetric flow rate, (d) includes flow the reaction inhibitor to the chamber at a second volumetric flow rate, and wherein a ratio of the first volumetric flow rate to the second volumetric flow rate is at least 100:1. In some such embodiments, the ratio is at least 1000:1. In some embodiments, the reaction inhibitor is introduced to the chamber during (c).

In some embodiments, the reaction inhibitor includes a halogen. In some embodiments, the reaction inhibitor is nitrogen trifluoride (NF₃) or plasma species generated from NF₃.

In some embodiments, the co-reactant plasma is an oxidizing plasma. In some embodiments, the co-reactant plasma is nitriding plasma.

In some embodiments, the method further includes performing a plurality of cycles (a)-(d), wherein at least one reaction inhibitor parameter is modified at least once during the plurality of cycles, the reaction inhibitor parameter selected from reaction inhibitor timing, reaction inhibitor volumetric flow rate, and reaction inhibitor concentration.

In some embodiments, the method further includes performing one or more cycles (a)-(c) without (d). In some embodiments, a flow of reaction inhibitor is stopped prior to the end of (c). In some embodiments, the reaction inhibitor selectively inhibits deposition of the film at the top of the gap.

These and other aspects of the disclosure are discussed further below with reference to the drawings.

### BRIEF DESCRIPTION OF THE DRAWINGS

FIG. 1 shows an illustration of an example of filling gaps in accordance with disclosed embodiments.

FIG. 2 shows an example of process sequence that may be used in accordance with the disclosed embodiments.

FIGS. 3a-3d show examples of timing sequences for atomic layer deposition (ALD) cycles that may be used in accordance with the disclosed embodiments.

FIG. 4 is a process flow diagrams depicting operations for a method in accordance with disclosed embodiments.

FIG. 5 is a graph showing growth per cycle as a function of inhibitor flow rate.

FIG. 6 is a schematic diagram of an example process station for performing disclosed embodiments.

FIG. 7 is a schematic diagram of an example process tool for performing disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to silicon-containing films such as silicon oxide, and related systems and apparatuses. The methods described herein can be used to fill vertically oriented features formed in a substrate. Such features may be referred to as gaps, recessed features, negative features, unfilled features, or simply features. Filling such features may be referred to as gap fill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to atomic layer deposition (ALD) of dielectric material in gaps that facilitates void-free bottom-up gap fill. An inhibitor is flowed during the ALD process. An inhibitor is a compound that creates a passivated surface and increase a nucleation barrier of the deposited ALD film. In some embodiments, the inhibitor is flowed during a plasma operation of a plasma-enhanced ALD (PEALD) process.

When the inhibitor interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. As a result, bottom-up fill is enhanced, which creates a more favorable sloped profile that mitigates the seam effect and prevents void formation.

Halogen-containing species in plasmas can be effective inhibitors. For example, in some embodiments, nitrogen trifluoride (NF₃) may be used.

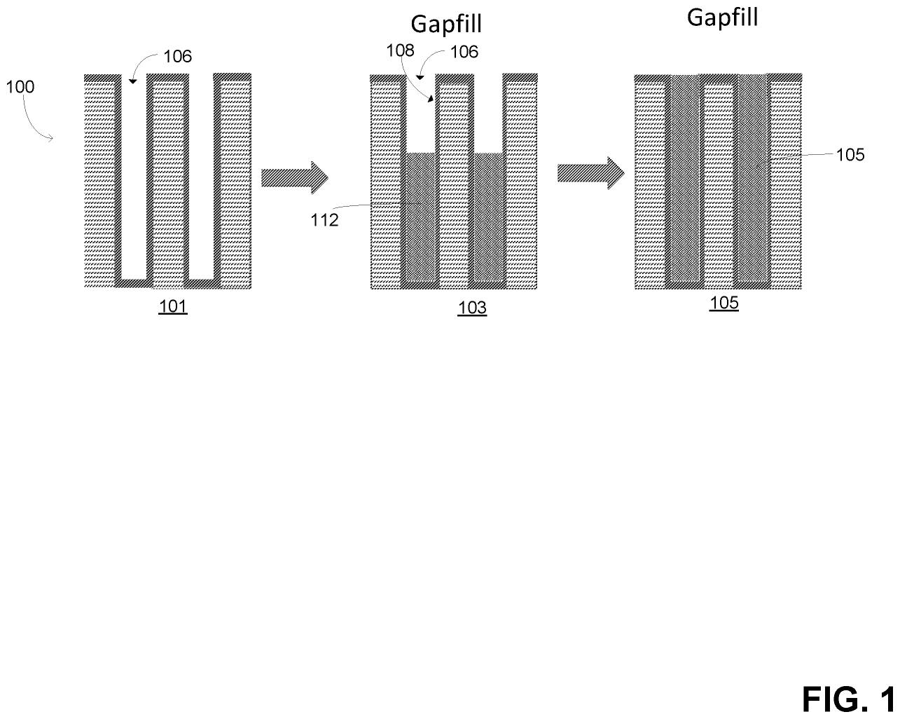

FIG. 1 is an example of bottom up fill using the methods described herein. A structure 100 includes a gap 106 to be filled with dielectric material. The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gap fill other substrates, such as glass, plastic, and the like, including in the fabrication of microelectromechanical (MEMS) devices.

Examples of structures include 3D NAND structures, DRAM structures, and shallow trench isolation (STI) structures. The structures include gaps with the sidewalls of the gaps formed by a material susceptible to etch. In one example, 3D NAND structure includes oxide-nitride-oxide-nitride (ONON) stacks covered with a poly Si layer. Other examples of sidewall materials include oxides, metals, and semiconducting materials.

At 103, the gaps 106 are partially filled with a dielectric material 112. The gaps 106 are filled with dielectric material 112 in a bottom-up manner, such that there is relatively little or no deposition on the sidewalls above the fill line. This is due to the inhibition plasma, which passivates the upper sidewall surfaces 108. At 105, the gaps are filled with dielectric material 112. As the deposition progresses, the surface inhibition effect is overcome, allowing the gap to be completely filled as shown at 105.

The gaps 106 in FIG. 1 are oriented vertically and are generally orthogonal with respect to the plane of the underlying substrate. Further examples of structures that may be filled with the methods described herein include lateral structures such as 3D-DRAM structures. In such structures, a gap is oriented generally parallel with respect to the plane of the underlying semiconductor substrate. Such a gap may have one or more openings. An inhibition plasma may inhibit the sidewalls near the gap opening to deposit material in the interior of the gap.

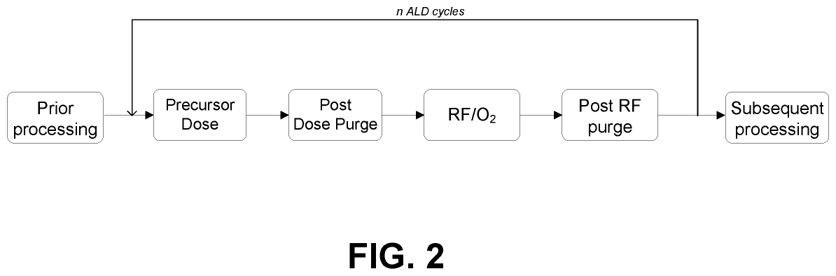

FIG. 2 shows an example of a process sequence that may be used in accordance with the disclosed embodiments. In the example process sequence of FIG. 2, one or more wafers undergo gap fill. The process includes prior processing operations. Examples include a soak after being provided to a deposition chamber and deposition of a protective liner film at the top of the gap. A soak can be useful, for example, to remove particles or other pretreatment. A protective liner can be useful if the sidewall surface is a sensitive material that may be damaged by the inhibitor plasma species.

Then, n cycles of PEALD deposition of are performed. ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations. PEALD processes use a plasma to provide energy to one or more operations.

As an example, an PEALD cycle may include the following operations: (i) delivery/adsorption of a precursor, (ii) purging of the precursor from the chamber, (iii) delivery of a second reactant and plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

In the example of FIG. 2, the second reactant is oxygen (O₂). However, other reactants may be used including other oxidants to deposit oxides, nitrogen-containing reactants to deposit nitrides, carbon-containing reactants to deposit carbides, etc. Examples include O₂ and/or nitrous oxide (N₂O) to form a silicon oxide layer or silicon oxynitride layer, nitrogen (N₂) or ammonia (NH₃) to form a silicon nitride layer, methane (CH₄) to generate a silicon carbide layer etc. Appropriate mixtures of reactants may be used to form oxycarbides, oxycarbonitrides, oynitrides, carbonitries, etc . . . . Examples of silicon-containing reactants are given below.

After the n cycles of ALD deposition are completed, post-processing may be performed. For example, a cap or overburden layer of dielectric may then be deposited. Plasma enhanced chemical vapor deposition (PECVD) may be used at this stage for a fast deposition.

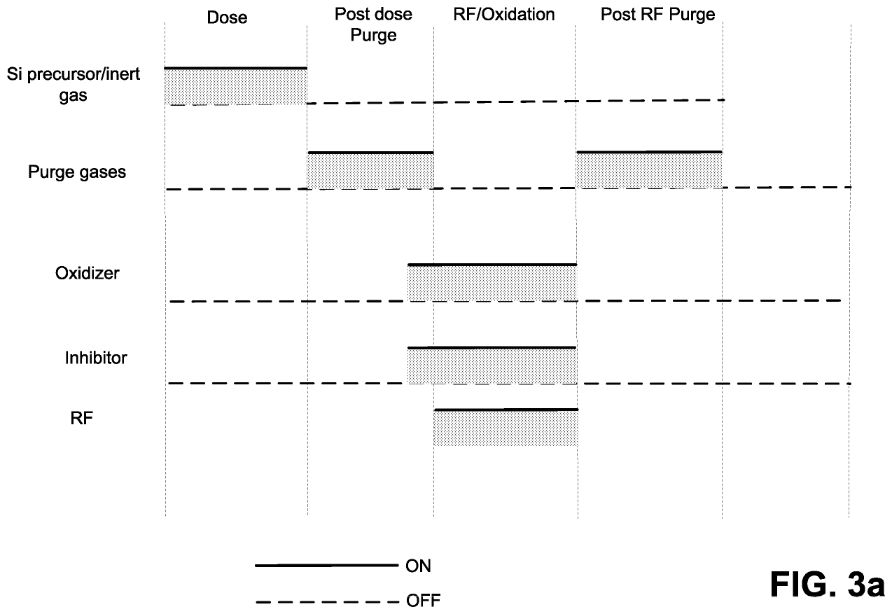

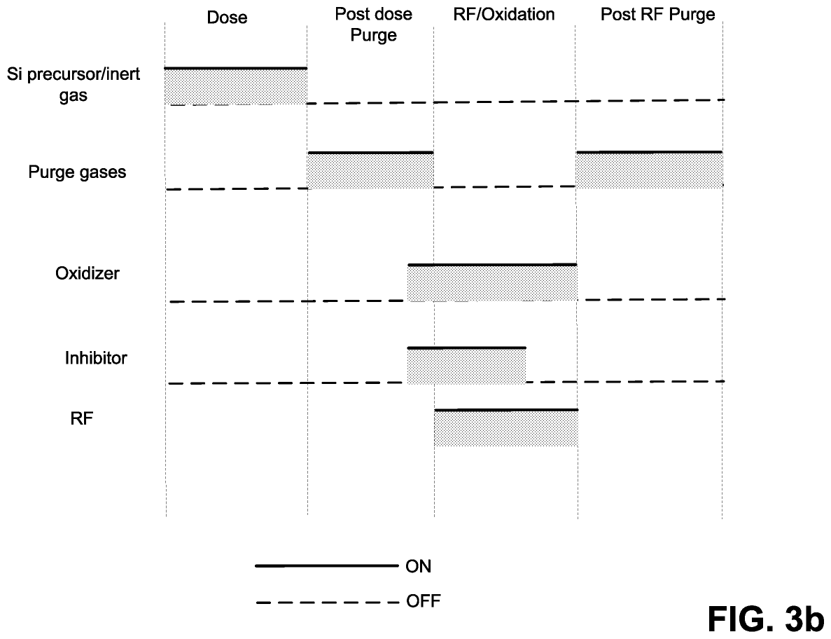

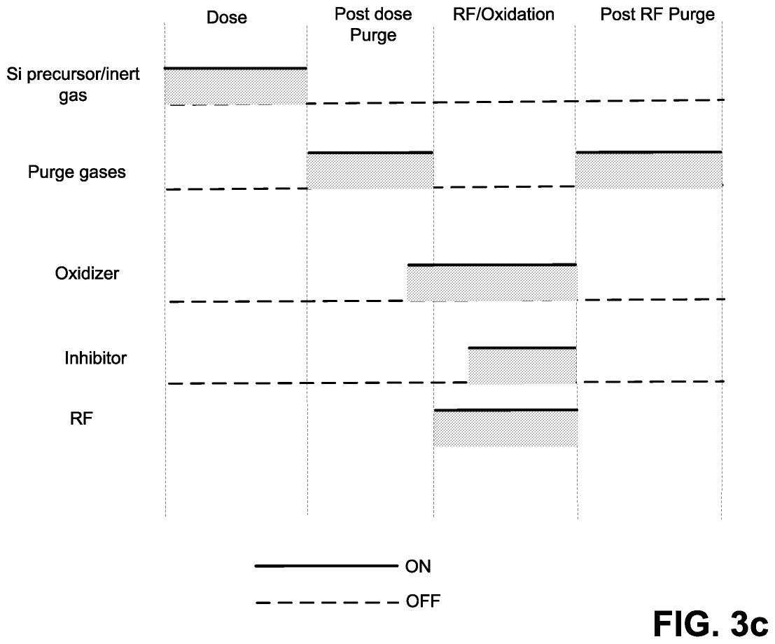

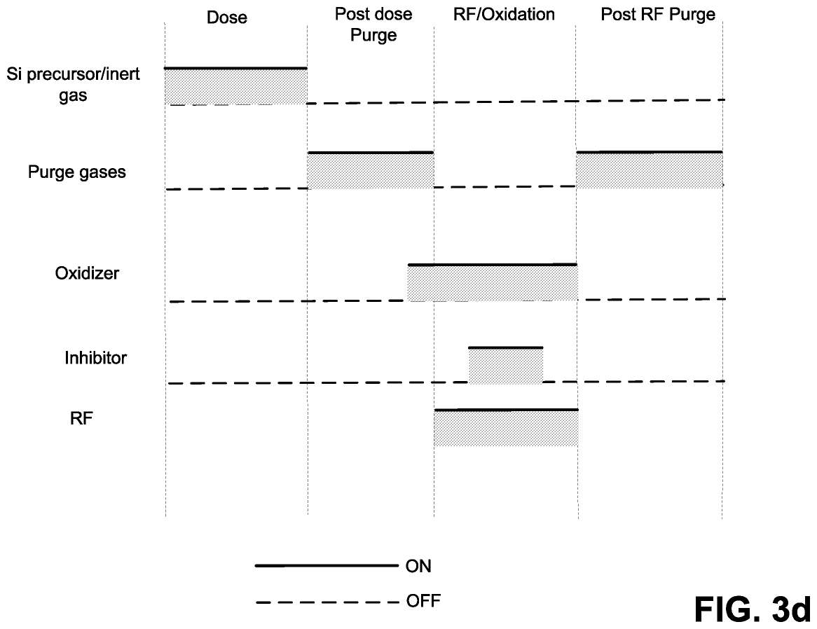

In the embodiments described herein an inhibitor is flowed during at least part of the RF operation shown in FIG. 2. An example timing diagram of a cycle is shown in FIG. 3a. The gas flows in the timing diagram may represent valves opening and/or the flowing of gas into a chamber housing the substrate. In the example of FIG. 3a, an inhibitor is flowed into the chamber prior to plasma ignition and throughout the RF/oxidation operation.

The timing sequence shown in FIG. 3a is an example and various deviations may be implemented within the scope of disclosure. For example, some amount of gas precursor may continue to flow into a chamber after a valve is closed. Still further, while the inhibitor and oxidizer flows are shown as beginning at the same time, these may be independently controlled. Still further, while an oxidizer is shown in FIGS. 3a-3d, a different co-reactant may be used for nitridation, etc.

The degree and depth of inhibition may be controlled by one or more of inhibitor flow rate, inhibitor dilution, and timing. FIG. 3b shows another example of a timing sequence in which the inhibitor flow is shut off prior to the end of the RF/oxidation operation. By controlling the depth of inhibition, dielectric is selectively deposited at the bottom of the feature and not on the inhibited surfaces. Further examples of inhibitor timing are given in FIGS. 3c and 3d. In FIG. 3c, the inhibitor flow starts after the onset of the RF phase and ends with the RF. In FIG. 3d, the inhibitor flow starts after the onset of the RF phase and ends before the RF ends.

Inhibitor flow rate may be significantly lower than that off the oxidant or other reactant flowed during the plasma operation. For example, for O₂ as an oxidant and NF₃ as an inhibitor, example flow rates may be 5 to 10 liters per minute (1 pm) O₂ and 10 to 20 standard cubic centimeters per minute (sccm) NF₃. These flow rates may vary depending on the feature geometry, reactant, and inhibitor. Regardless of these parameters, the reactant (e.g., oxidant or nitriding agent) flow rate will typically be significantly higher than that of the According to various embodiments, the oxidant or other reactant flowed during the RF stage will have a volumetric flow rate at least 10, at least 100, at least 500, or at least 1000 times higher than that of the inhibitor.

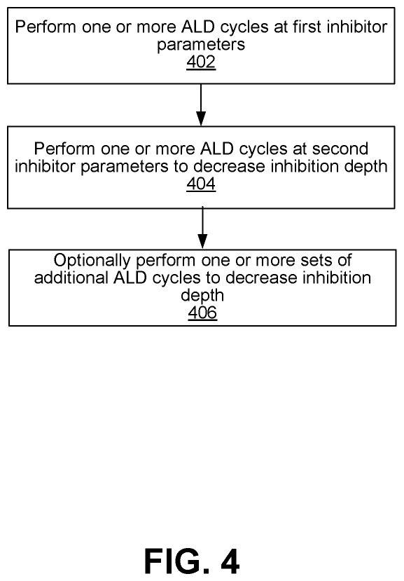

As a gap is filled, the inhibition depth may be decreased to allow deposition on previously inhibited regions of the gap. FIG. 4 is a process flow diagram that shows an example of a method of filling a gap in which the inhibition depth is decreased. One or more ALD cycles are performed using first inhibitor parameters of a parameter set in an operation 402. Inhibitor parameters including timing (especially with respect to plasma ignition and extinguishment), flow rate, and concentration or dilution. After the gap has been partially filled, the method proceeds with one or more ALD cycles using second inhibitor parameters of the parameter set in an operation 404. At least one of the parameters is changed to decrease the inhibition depth such that the inhibitor does not extend as far into the gap. For example, the inhibitor dose time may be reduced and/or the inhibitor flow rate may be decreased. In some embodiments, the identity of the inhibitor may be changed, switching from a stronger to weaker inhibitor. In an operation 406, one or more additional sets of ALD cycles may be performed to decrease the inhibition depth. The same or different parameter or parameters as changed in operation 404 may be changed in each set of ALD cycles of operation 406.

In some embodiments, parameters that are not specific to the inhibitor may be adjusted in addition to or instead of inhibitor-specific parameters. These can include RF power and pressure.

In some embodiments, some ALD cycles are performed without an inhibitor. This can increase deposition rate. The inhibitor-free cycles may be performed at any appropriate time. In some embodiments, the inhibitor-free cycles may be performed at routine intervals. For example, one or more inhibitor-free cycle may be performed every mth cycle, where m is an integer greater than 1. The frequency of inhibitor-free cycles may be an inhibitor parameter in the method of FIG. 4. In some embodiments, inhibitor-free cycle may be performed once the gap has been filled to a certain point. In some embodiments, a set of inhibitor-free cycles may be performed consecutively.

It should be noted that the processes described herein are not limited to a particular reaction mechanism. Thus, the processes described above includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

While the above description refers chiefly to PEALD processes using RF power, modifications may be made. In some embodiments, the PEALD process uses an in-situ plasma that is generated in the chamber in which the substrate is housed. In other embodiments, a remotely-generated plasma may be used. In some embodiments, a remotely-generated plasma may be characterized by having substantially no ionic species. For example, atomic oxygen generated in a remote plasma chamber may be used as a co-reactant. An inhibitor may be flowed while the remotely generated plasma is introduced to the chamber housing the substrate. According to various embodiments, the inhibitor may also be used to generate a remote plasma during some or all of the plasma operation or may be flowed separately to the chamber. In some embodiments, the methods are performed using thermal ALD processes. In such embodiments, the inhibitor may be flowed during part or all of the ALD process or the co-reactant stage.

For depositing silicon oxide, one or more silicon-containing precursors may be used. Silicon-containing precursors suitable for use in accordance with disclosed embodiments include polysilanes (H₃Si—(SiH₂)ₙ—SiH₃), where n≥0. Examples of silanes are silane (SiH₄), disilane (Si₂H₆), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino) silane (SiH₂ (NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3 MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some embodiments., silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R¹, R², R³ and R⁴ is hydrogen, unbranched alkyl, branched alkyl, saturated heterocyclic, unsaturated heterocyclic groups, or combinations thereof. In some embodiments, when at least one X or Y is NR³R⁴, R³ and R⁴, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-see butylamino-1,1-dimethyl disiloxane, 1-N-methylethylamino-1,1-dimethyl disiloxane, 1-N methylpropylamino-1,1-dimethyl disiloxan,e 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (CH₁₇N), di-t-butylhydrazine (C₈H₂ON₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

According to various embodiments, the inhibitor is a halogen-containing compound such that the plasma includes halogen species. Examples of such species include anion and radical species such as F⁻, Cl⁻, I⁻, Br⁻, fluorine radicals, etc. In some embodiments, the plasma is generated from NF₃. Other inhibition plasmas may be used. For example, plasmas generated from molecular nitrogen (N₂), molecular hydrogen (H₂), ammonia (NH₃), amines, diols, diamines, aminoalcohols, thiols or combinations thereof may be used as inhibition plasmas. A plasma generated from a halogen-containing compound such as NF₃ may provide an inhibition effect in a substantially reduced time compared to a plasma generated from a non-halogen such as molecular nitrogen (N₂). In some embodiments, the inhibitor is a hydrocarbon, e.g., CH₄.

In various embodiments, the plasma is an in-situ plasma, such that the plasma is formed directly above the substrate surface in the station. Example power per substrate areas for an in-situ plasma are between about 0.2122 W/cm² and about 2.122 W/cm² in some embodiments. For example, the power may range from about 600 W to about 6000 W for a chamber processing four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

As described below, high frequency RF (HFRF) is used for the plasma in many embodiments. In some embodiments, during the oxidation or nitridation, the RF is supplied with a low frequency (LF) component as well as an HF component. Example HF frequencies is about 13.56 or 27 MHz and example LF frequencies are between about 300-400 kHz. The presence or amount of HF and/or LF power may be varied as an inhibitor parameter in FIG. 4 in some embodiments.

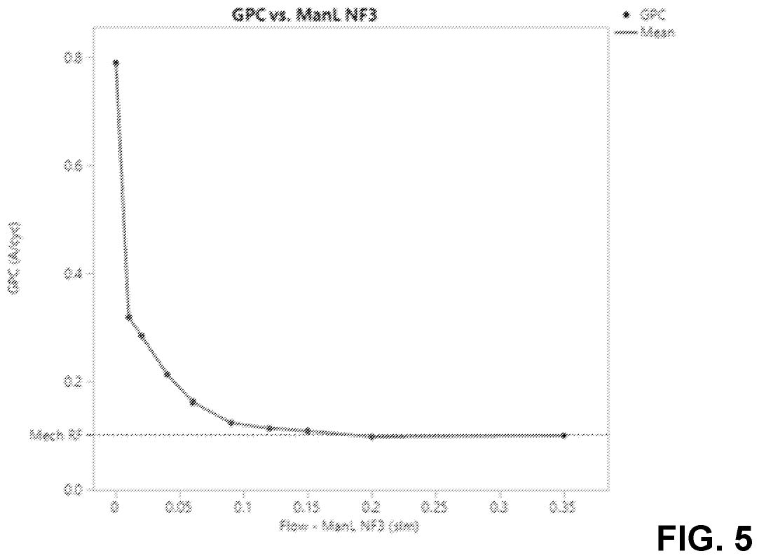

FIG. 5 is a graph showing growth per cycle (GPC) of a silicon oxide film as a function of inhibitor (NF₃) flow rate on a blanket surface in an ALD process as described above. As shown in the graph, the growth per cycle is tunable and can be fully stopped with sufficient NF₃ flow.

The table below shows processing times for various inhibition processes, with the inhibition processes described herein compared with standard PEALD (no inhibition) and processes that use a separate inhibition plasma without flowing the inhibitor during the deposition cycle.

Process A: PEALD with no inhibition.
Processes B-D: Separate inhibition plasma and PEALD cycle.
Process E: Inhibition during PEALD cycle

| | | Inhibition | | |
|---|---|---|---|---|
| | PEALD | plasma + | | Inhibition |
| | cycle | purge | Effective ALD | strength/ |
| Process | time (s) | time (s) | cycle time | depth |
| A—standard | 1.2 | 0 | 1.2 | None/0 |
| PEALD | | | | |
| B—1 inhibition | 1.2 | 3 | 1.5 (+25% | Weak/ |
| plasma every 10 | | | compared to | shallow |
| PEALD cycles | | | standard PEALD) | depth |
| C—1 inhibition | 1.2 | 3 | 1.8 (+50% | Medium/ |
| plasma every 10 | | | compared to | medium |
| PEALD cycles | | | standard PEALD) | depth |
| D—1 inhibition | 1.2 | 3 | 4.2 (+350% | Strong/deep |
| plasma every 10 | | | compared to | depth |
| PEALD cycles | | | standard PEALD) | |
| E—Inhibition | 1.2 | 0 | 1.2 | Tunable |
| during each | | | | with NF₃ |
| PEALD cycle | | | | settings |

The results in the table show that the processes described herein provide significant throughput advantages over other methods, particularly when for processes that use strong and/or deep inhibition.

### Apparatus

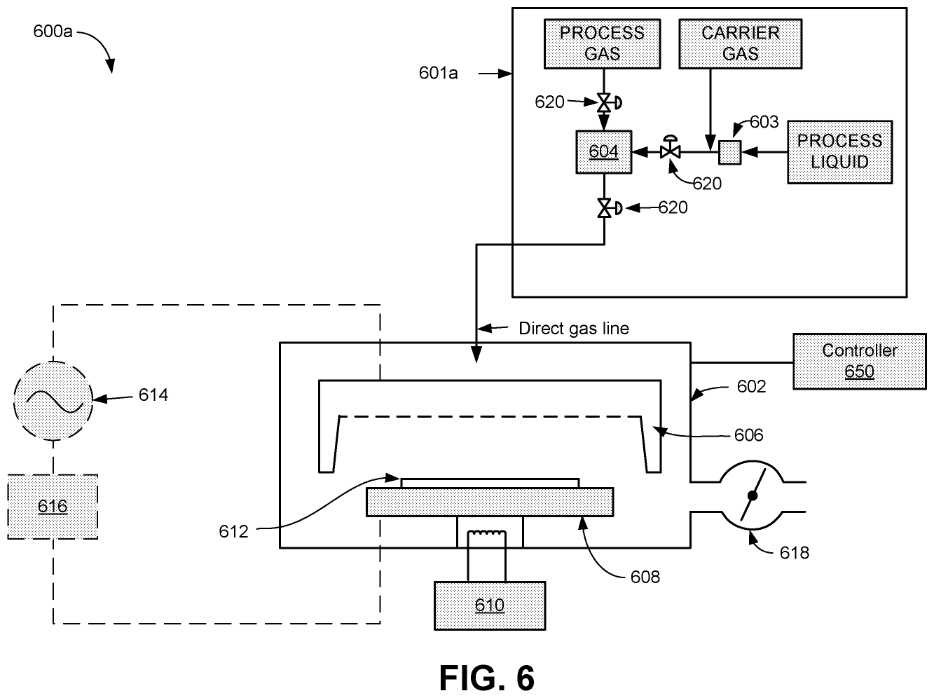

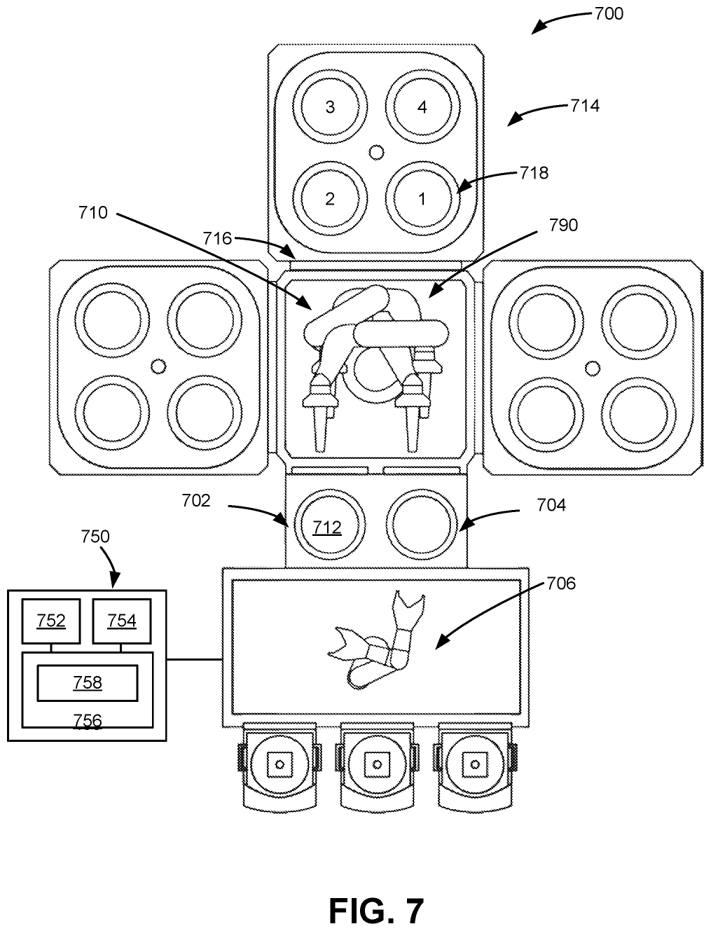

FIG. 6 depicts a schematic illustration of an embodiment of an atomic layer deposition (ALD) process station 600 having a process chamber body 602 for maintaining a low-pressure environment. A plurality of ALD process stations 600 may be included in a common low-pressure process tool environment. For example, FIG. 7 depicts an embodiment of a multi-station processing tool 700. In some embodiments, one or more hardware parameters of ALD process station 600, including those discussed in detail below, may be adjusted programmatically by one or more system controllers 650.

ALD process station 600 fluidly communicates with reactant delivery system 601a for delivering process gases to a distribution showerhead 606. Reactant delivery system 601a includes a mixing vessel 604 for blending and/or conditioning process gases for delivery to showerhead 606. In some embodiments, an inhibitor gas may be introduced to the mixing vessel prior to introduction to the chamber body 602, such as if provided with a carrier gas. In some embodiments, an inhibitor or other gas may be directly delivered to the chamber body 602. One or more mixing vessel inlet valves 720 may control introduction of process gases to mixing vessel 604. These valves may be controlled depending on whether a process gas, inhibitor gas, or carrier gas may be turned on during various operations. In some embodiments, an inhibitor gas may be generated by using an inhibitor liquid and vaporizing using a heated vaporizer.

As an example, the embodiment of FIG. 6 includes a vaporization point 603 for vaporizing liquid reactant to be supplied to the mixing vessel 604. In some embodiments, vaporization point 603 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100° C. to approximately 150° C. at mixing vessel 704.

In some embodiments, liquid precursor or liquid reactant, such as a silicon-containing precursor, may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 706.

In some embodiments, a liquid flow controller (LFC) (not shown) upstream of vaporization point 603 may be provided for controlling a mass flow of liquid for vaporization and delivery to process station 600. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 606 distributes gases toward substrate 612. For example, showerhead 606 may distribute an inhibitor gas to the substrate 612, silicon-containing precursor gas to the substrate 612, or a purge or carrier gas to the chamber body 602, a second reactant to the substrate 612, or a passivation gas to the substrate 612, in various operations. In the embodiment shown in FIG. 6, the substrate 612 is located beneath showerhead 606 and is shown resting on a pedestal 608. Showerhead 606 may have any suitable shape and may have any suitable number and arrangement of ports for distributing process gases to substrate 612.

In some embodiments, a microvolume is located beneath showerhead 606. Practicing disclosed embodiments in a microvolume rather than in the entire volume of a process station may reduce reactant exposure and purge times, may reduce times for altering process conditions (e.g., pressure, temperature, etc.) may limit an exposure of process station robotics to process gases, etc. Example microvolume sizes include, but are not limited to, volumes between 0.1 liter and 2 liters. This also impacts productivity throughput. In some embodiments, the disclosed embodiments are not performed in a microvolume.

In some embodiments, pedestal 608 may be raised or lowered to expose substrate 612 to microvolume 607 and/or to vary a volume of microvolume 607. For example, in a substrate transfer phase, pedestal 608 may be raised to position substrate 612 within microvolume 607. In some embodiments, microvolume 607 may completely enclose substrate 612 as well as a portion of pedestal 608 to create a region of high flow impedance.

Optionally, pedestal 608 may be lowered and/or raised during portions the process to modulate process pressure, reactant concentration, etc., within microvolume 607. In one scenario where process chamber body 602 remains at a base pressure during the process, lowering pedestal 608 may allow microvolume 607 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller 650.

In another scenario, adjusting a height of pedestal 608 may allow a plasma density to be varied during optional plasma activation processes. For example, the plasma may be activated when the inhibitor gas is introduced to the chamber body 602, or when the second reactant is flowed to the chamber body 602. In some embodiments, a plasma may not be activated during flow of the inhibitor gas or the flow of the second reactant. At the conclusion of the process phase, pedestal 608 may be lowered during another substrate transfer phase to allow removal of substrate 612 from pedestal 608.

While the example microvolume variations described herein refer to a height-adjustable pedestal 608, it will be appreciated that, in some embodiments, a position of showerhead 606 may be adjusted relative to pedestal 608 to vary a volume of microvolume 607. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable controllers 650.

Showerhead 606 and pedestal 608 electrically communicate with a radio frequency (RF) power supply 614 and matching network 616 for powering a plasma. In some embodiments, the plasma energy may be controlled by controlling one or more of a process station pressure, gas concentrations and partial pressures of gases or gas flow rates, an RF source power, an RF source frequency, and a plasma power pulse timing. For example, RF power supply 614 and matching network 616 may be operated at any suitable power to form a plasma having a desired composition of radical species. Examples of suitable powers are included above. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHZ, or greater than about 13.56 MHz, or greater than 27 MHz, or greater than 40 MHZ, or greater than 60 MHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor such as disilane), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for setting a flow rate of an inert, inhibitor and/or reactant gas which may be the same as or different from the gas used in the first recipe phase (e.g., a hydrogen-containing inhibitor), instructions for modulating a flow rate of a carrier gas, and time delay instructions for the third recipe phase. A fourth recipe phase may include instructions for modulating or stopping a flow rate of an inert and/or a reactant gas (e.g., a second reactant such as nitrogen or a nitrogen-containing or oxygen-containing gas), instructions for modulating the flow rate of a carrier or purge gas, and time delay instructions for the fourth recipe phase. It will be appreciated that these recipe phases may be further subdivided and/or iterated in any suitable way within the scope of the present disclosure.

In some embodiments, pedestal 608 may be temperature controlled via heater 610. Further, in some embodiments, pressure control for process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to the process station 600.

As described above, one or more process stations may be included in a multi-station processing tool. FIG. 7 shows a schematic view of an embodiment of a multi-station processing tool 700 with an inbound load lock 702 and an outbound load lock 704, either or both of which may include a remote plasma source. A robot 706, at atmospheric pressure, is configured to move wafers from a cassette into inbound load lock 702. A wafer is placed by the robot 706 on a pedestal 712 in the inbound load lock 702, the atmospheric port 710 is closed, and the load lock is pumped down. Where the inbound load lock 702 includes a remote plasma source, the wafer may be exposed to a remote plasma treatment in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and a robot places the wafer into the reactor on a pedestal of a first station shown in the reactor for processing. While the embodiment depicted in FIG. 7 includes load locks, it will be appreciated that, in some embodiments, direct entry of a wafer into a process station may be provided.

The depicted processing chamber 714 includes four process stations, numbered from 1 to 4 in the embodiment shown in FIG. 7. Each station has a heated pedestal (shown at 718 for station 1), and gas line inlets. It will be appreciated that in some embodiments, each process station may have different or multiple purposes. While the depicted processing chamber 714 includes four stations, it will be understood that a processing chamber according to the present disclosure may have any suitable number of stations. For example, in some embodiments, a processing chamber may have five or more stations, while in other embodiments a processing chamber may have three or fewer stations.

Each station may perform the same or different operations as another station. In some embodiments, inhibition is performed only at one or a subset of stations.

FIG. 7 depicts an embodiment of a wafer handling system 790 for transferring wafers. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog and/or digital input/output connections, stepper motor controller boards, etc.

In some embodiments, system controller 750 controls all the activities of process tool 700. System controller 750 executes system control software 758 stored in mass storage device 754, loaded into memory device 756, and executed on processor 7752. Alternatively, the control logic may be hard coded in the controller 750. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 758 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 700. System control software 758 may be configured in any suitable way. For example, various process tool component subroutines or control objects may be written to control operation of the process tool components used to carry out various process tool processes. System control software 758 may be coded in any suitable computer readable programming language.

In some embodiments, system control software 758 may include input/output control (IOC) sequencing instructions for controlling the various parameters described above. Other computer software and/or programs stored on mass storage device 754 and/or memory device 856 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling gas composition (e.g., silicon-containing precursor, co-reactant, inhibition, passivation, and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 750 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 750 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 750.

In some implementations, the system controller 750 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases and/or inhibitor gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 750, in some implementations, may be a part of or coupled to a computer that is integrated with, coupled to the system, otherwise networked to the system, or a combination thereof. For example, the system controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. The parameters may be specific to the type of process to be performed and the type of tool that the system controller 750 is configured to interface with or control. Thus, as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 750 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for filling a gap of a substrate in a chamber, the method comprising:
performing one or more cycles of:
(a) exposing the substrate to a first reactant;
(b) after (a), purging the chamber of the first reactant;
(c) after (b), exposing the substrate to a co-reactant plasma to drive a reaction between the first reactant and the co-reactant to form a film in the gap; and
(d) exposing the substrate to a reaction inhibitor during at least part of (c).

2. The method of claim 1, wherein the film is a silicon-containing film.

3. The method of claim 1, wherein the film is an oxide, a nitride, or a carbide.

4. The method of claim 1, wherein (c) comprises flowing a co-reactant to the chamber at a first volumetric flow rate, (d) comprises flow the reaction inhibitor to the chamber at a second volumetric flow rate, and wherein a ratio of the first volumetric flow rate to the second volumetric flow rate is at least 100:1.

5. The method of claim 4, wherein the ratio is at least 1000:1.

6. The method of claim 1, wherein the reaction inhibitor is introduced to the chamber during (c).

7. The method of claim 1, wherein the reaction inhibitor comprises a halogen.

8. The method of claim 1, wherein the reaction inhibitor is nitrogen trifluoride (NF₃) or plasma species generated from NF₃.

9. The method of claim 1, wherein the co-reactant plasma is an oxidizing plasma.

10. The method of claim 1, wherein the co-reactant plasma is nitriding plasma.

11. The method of claim 1, further comprising performing a plurality of cycles (a)-(d), wherein at least one reaction inhibitor parameter is modified at least once during the plurality of cycles, the reaction inhibitor parameter selected from reaction inhibitor timing, reaction inhibitor volumetric flow rate, and reaction inhibitor concentration.

12. The method of claim 1, further comprising performing one or more cycles (a)-(c) without (d).

13. The method of claim 1, wherein a flow of reaction inhibitor is stopped prior to the end of (c).

14. The method of claim 1, wherein the reaction inhibitor selectively inhibits deposition of the film at the top of the gap.
